(19) United States
(12) Patent Application Publication
(10) Pub. No.: US 2026/0276699 A1
(43) Pub. Date: Sep. 17, 2026

(54) METHOD AND SYSTEM FOR TESTING THE RESILIENCE OF AN ELECTRONIC DEVICE THAT IN USE IS SUBJECTED TO PERIODIC DEFORMATIONS

(71) Applicant: Bridgestone Europe NV/SA [BE/BE], Zaventem (BE)

(72) Inventors: Mattia Antonio Ciampa, Roma (IT); Francesco Iozia, Roma (IT)

(21) Appl. No.: 18/875,747

(22) PCT Filed: Jun. 16, 2023
(86) PCT No.: PCT/IB2023/056263

§ 371 Date: Dec. 17, 2024

(30) Foreign Application Priority Data
Jun. 17, 2022 (IT) 102022000012863

(51) Int. Cl. G01R 31/28

(52) U.S. Cl. CPC G01R 31/287; G01R 31/2875; G01R 31/2877; G01R 31/2881

(57) ABSTRACT

A method and system are provided for testing the resilience of an electronic device coupled to a component of a tire. The following steps are provided for: determining a first form which the component assumes in use; determining a second form which the component assumes in use and that is different than the first form; making a support containing the electronic device; subjecting an area of the support wherein an electronic device is arranged, to a series of cyclical deformations in such a way that said area may alternatively assume the first form and the second form; and detecting the operation of the electronic device during the cyclical deformations of the support.

### TECHNICAL SECTOR

The present invention relates to a method and to a system for testing an electronic device that in use is subjected to periodic deformations.

The present invention finds advantageous application in testing the resilience of an electronic device that is intended to be coupled to a component of a tire, whereto the following description will make explicit reference without therefore losing the generality thereof.

### PRIOR ART

In recent years, so-called “smart” tires have emerged, which are capable of forming an active part of modern vehicles, supplying information concerning the type of tires mounted, information concerning the state of the tires and also information concerning ambient and road conditions.

A “smart” tire is normally equipped with a transponder (that is to say an electronic device suitable for communicating in radio frequency) which permits remote communication (that is to both the vehicle whereupon the tire is mounted and to an operator who must carry out the checking or the replacement of the tire in either using automatic systems or else in proximity to the vehicle itself) of the identification, the characteristics and the history of the tire.

Recently, the integration has been proposed of RFID (“Radio-Frequency IDentification”) technology, based upon the presence of transponders, and TPMS (“Tire Pressure Monitoring Systems”) technology, which measures the effective inflation pressure in order to store within transponders the effective inflation pressure and then remotely communicate the effective inflation pressure by means of the transponders themselves.

Generally, a transponder that is intended to be coupled to a tire is first inserted into a rubber support (housing). Such a rubber support may completely incorporate the transponder on all sides or else also only partially. Subsequently, in order to couple a transponder to a tire, it is possible to attach the transponder to an inner or outer surface of the tire (typically above the innerliner which has the task of ensuring the air tightness of the tire itself) or else it is possible to integrate the transponder into those components that constitute the structure of the tire (i.e., arrange the transponder in the middle of the various layers that make up the tire).

During use (that is to say when rolling over a road surface) at the part of the tire that is found to be in contact with the road surface (constituting the so called “footprint on the ground”) the tire is subjected to continuous deformations of significant magnitude and, due to the rolling effect, the part of the tire that is found to be in contact with the road surface varies continuously. Consequently, during use, a transponder that is coupled to a tire component is subjected to the same cyclical deformations that the component is subjected to and therefore, in the long run, it may be subject to fatigue fracture (this is typically reflected as an interruption to the electrical continuity of the chip and/or to the radiofrequency transmission elements such as, for example, the antennas that are relatively large.

It is therefore necessary to test the effective resilience of a transponder (or other electronic device) that is coupled to a tire component in order to be able to ensure that the transponder continues to function for the entire life of the tire. Resilience tests are actually performed in constructing prototypes of the tire that comprise the transponder (or other electronic device) and in performing duration tests using such prototypes; these types of tests, even though they are very efficient (that is to say that the exhibit high precision and high reliability), are, however, not very efficient insofar as they are very long in duration and are very costly (the manufacture of only a few tire prototypes is a substantially manual operation with an extremely high associated cost).

The patent U.S. Pat. No. 8,063,742B2 describes a system for testing the resilience of an electronic device coupled to a tire component, wherein the tire component (centrally containing the electronic device) is engaged at the extremities and is cyclically made to slide around a succession of rollers arranged in sequence and defining a serpentine path; a reader is arranged alongside the rollers in order to cyclically interrogate the electronic device and to therefore determine if and when the electronic device stops functioning. This test system is efficient (that is to say that it makes it possible to perform tests over short periods of time and with reduced costs), but not particularly efficient insofar as the results supplied are not very precise and are not trustworthy (that is to say that the resilience measured by the test system is very often substantially different than the actual resilience to be encountered in tires that are fitted to vehicles) insofar as those deformations that are cyclically applied to the component (centrally containing the electronic device) are different than those deformations whereto the same component is subject during the actual use of the tire.

### Description of the Invention

The object of the present invention is that of supplying a method and system for testing the resilience of an electronic device that in use is subjected to periodic deformations and that is intended to be coupled to at least one component of an elastic body, preferably a tire, which method and system make it possible to efficiently (that is to say over short periods of time and with reduced costs) and effectively (that is to say with high precision and reliability) test the effective resilience of the electronic device taking into consideration the actual operating condition stresses.

According to the present invention a method and system are supplied for testing the resilience of an electronic device that in use is subjected to periodic deformations and that is intended to be coupled to at least one component of an elastic body, preferably a tire component, according to that established by the attached claims.

The claims describe preferred embodiments of the present invention that form an integral part of the present description.

### BRIEF DESCRIPTION OF THE DRAWINGS

The present invention will now be described with reference to the attached drawings, which illustrate an exemplary, non-limiting embodiment, wherein:

FIG. 1 is a schematic view and a transverse cross-sectional view of a tire provided with a transponder;

FIGS. 2 and 3 are, respectively, an undeformed view (unloaded) and a deformed view (loaded) of the tire of FIG. 1;

FIG. 4 is a schematic view of system for testing the resilience of an electronic device that is destined to be coupled to a tire component.

FIG. 5 is a perspective view of a detail of the testing system of FIG. 4; and

FIGS. 6 and 7 are two schematic views of a detail of FIG. 5 in two different instants of operation.

### PREFERRED EMBODIMENTS OF THE INVENTION

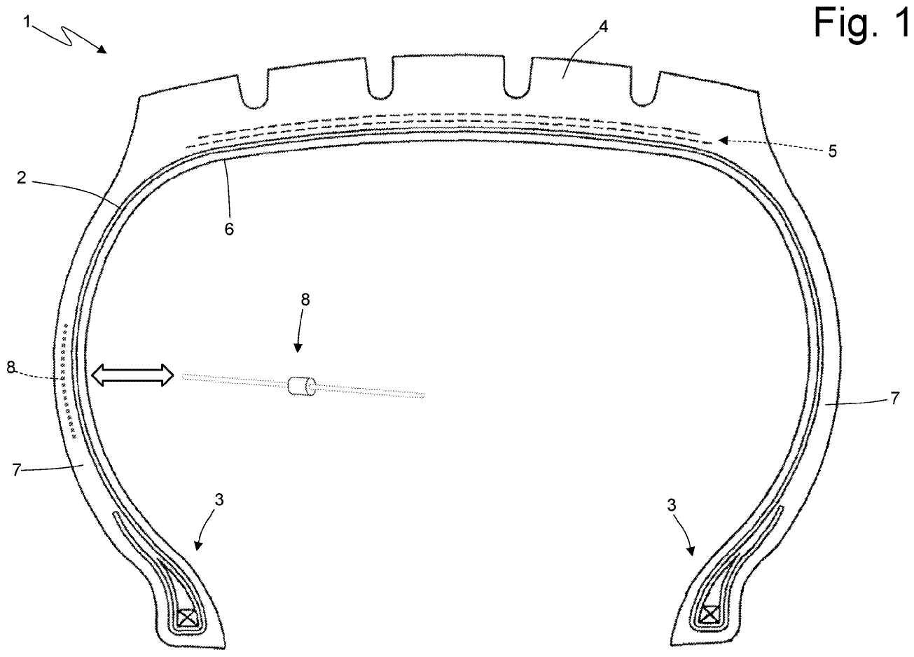

In FIG. 1, reference numeral 1 indicates as a whole a pneumatic tire 1 comprising a toroidal carcass 2, which is partially folded onto itself and therefore has two lateral flaps (i.e., two layers superimposed on one another and jointly referred to as a “turn-up”). Two annular beads 3 are provided at opposite sides of the carcass 2, wherein each thereof is surrounded by the carcass 2. The carcass 2 supports an annular tread 4 with the interposition of a tread belt 5. Arranged within the carcass 2 is an innerliner 6 which is airtight, constitutes an inner lining and has the function of retaining the air within the tire 1 in order to maintain the inflation pressure of the same tire 1 over time. The carcass 2 supports a couple of lateral walls 7, each of which links a bead 3 to the tread 4.

The tire 1 is provided with a transponder 8, that is to say an electronic device (usually passive, that is to say devoid of an electrical power supply thereof but an active or semi-passive transponder is not to be excluded) that is capable of storing information and/or acquiring signals in relation to operating conditions or else the state of the tire and it is capable of communicating by means of radio frequency. In other words, the transponder 8 is a “smart label” or intelligent sensor of small dimensions that is suitable for responding to remote polling on the part of specific fixed or portable devices, called readers (or polling devices); or else to autonomously transmit signals to a receiver; a reader or receiver is capable of reading and/or modifying the information contained within the transponder 8 communicating with the transponder 8 itself in radio frequency. Accordingly, the transponder 8 is part of a wireless reading and/or writing system that operates according to so-called RFID technology (“Radio-Frequency IDentification”).

According to what is shown in FIG. 1, the transponder 8 is coupled to a lateral wall 7 of the tire 1; according to other embodiments, not shown, the transponder 8 could be coupled to other components of the tire 1, other than the lateral wall 7, such as, for example, parts beneath the tread 4 or the sides thereof.

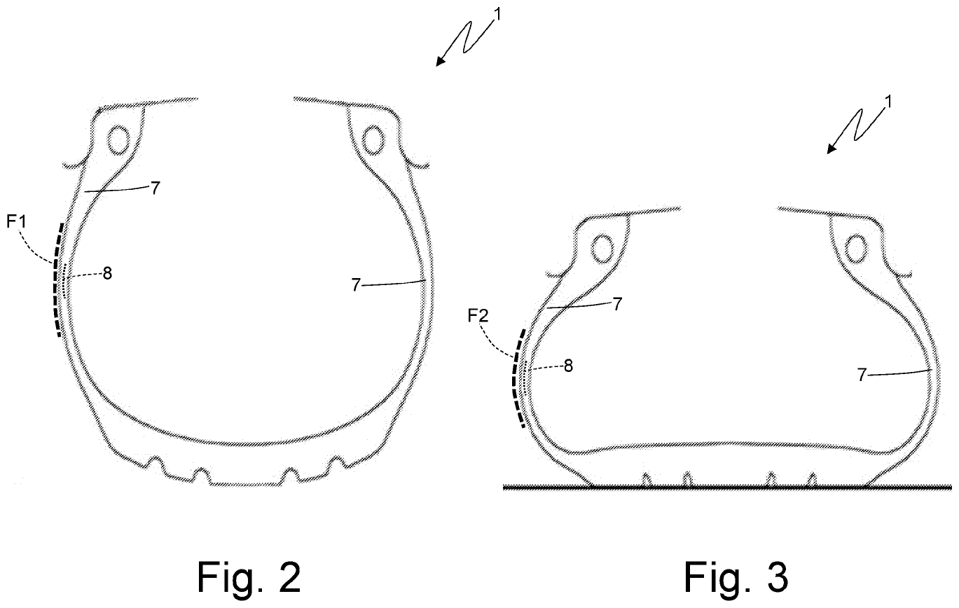

According to what is shown in FIGS. 2 and 3, during use (that is to say when rolling over a road surface) the tire 1 is subjected to continuous deformations of significant magnitude at the part of the tire 1 that is found to be in contact with the road surface (constituting the so called “footprint on the ground”) and, due to the rolling effect, the part of the tire 1 that is found to be in contact with the road surface continuously varies. Accordingly, during use, the transponder 8 coupled to a component (in particular to a lateral wall 7) of the tire 7 is subjected to the same cyclical deformations whereto the component is subjected (in particular the lateral wall 7). In FIG. 2 a section of the tire 1 is shown that is far from the road surface (that is to say from the so called “footprint on the ground”) and is therefore undeformed; in FIG. 3 on the other hand a section of the tire 1 is shown that is in contact with the road surface (that is to say at the so called “footprint on the ground”) and therefore deformed.

As shall be better clarified hereinafter, the tire 1 is first analyzed in order to determine (typically using simulations that are possibly confirmed in analyzing actual images) how the tire deforms three-dimensionally in use and generally under less favorable conditions, that is to say in the so called “worst case” (that is to say under “extreme” condition wherein the deformation is more accentuated and therefore with an elevated vertical load corresponding to the vehicle under full load and with reduced inflation pressure). In this way, beforehand, a three-dimensional form F1 is determined which the component (that is to say the lateral wall 7) containing the transponder 8) assumes in the tire 1 when it is far from the footprint on the ground and a three-dimensional form F2 is also determined that the component (that is to say the lateral wall 7) containing the transponder 8 assumes in the tire 1 when it is at the footprint on the ground. The three-dimensional form F1 has an average radius of curvature (in relation to the centerline of the section) that is greater than an average radius of curvature of the three-dimensional form F2; that is to say that the three-dimensional form F2 has a more pronounced curve (greater) than the three-dimensional form F1.

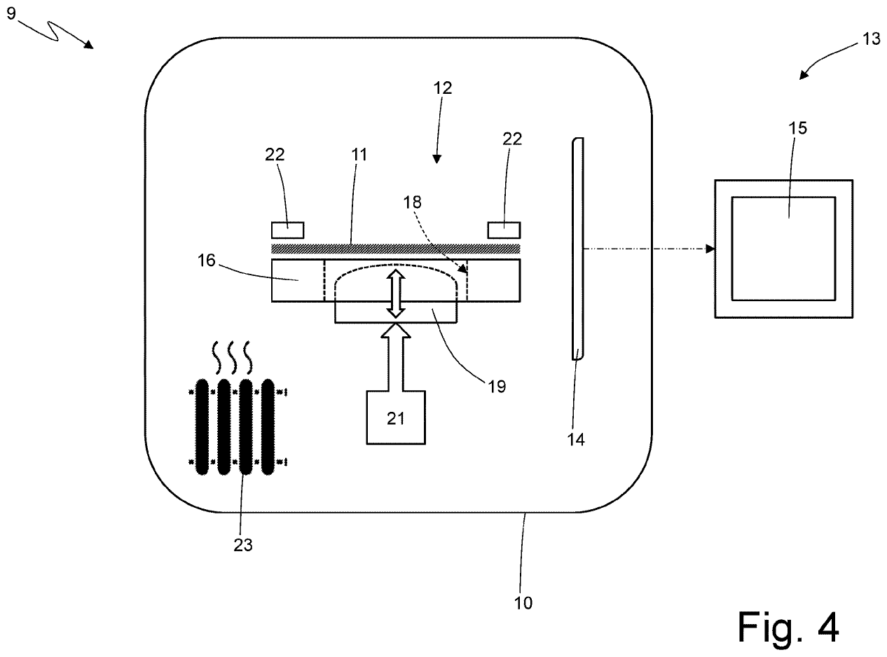

In FIG. 4, with the reference numeral 9, a system is indicated, in the entirety thereof, for testing the resilience of the transponder 8 coupled to a component (in particular a lateral wall 7) of the tire 1.

The test system 9 comprises a closed chamber 10 (provided with a door that may be opened) that, in order to be climate-controlled, is preferably thermally isolated (as will be better described hereinafter). The test system 9 uses a support (sample) 11 containing the transponder 8. In the embodiment shown in the attached figures, the support 11 has a rectangular form, but according to other embodiments not shown, the support 11 may also take other forms (for example a circular form, an elliptical form or else a polygonal form). In particular, the transponder 8 is preferably arranged within an area that is central to the support 11. According to a preferred embodiment the support 11 comprises a rubber housing that is composed of two layers of rubber that are joined together in order to enclose the transponder 8 therebetween, and it is the same rubber housing that is used in the production of the tires 1 for coupling the transponders 8 to the tires 1. In other words, in order to test the resilience of a transponder 8 that is intended to be coupled to a component (the lateral wall 7) of the tire 1, the support 11 is implemented, which contains the transponder 8, which is preferably arranged within an area that is central to the support 11 itself.

The test system 9 comprises a deforming unit 12 that is arranged inside the closed chamber 9 and that is configured to subject the central area of the support 11 containing the transponder 8 (that is to say an area of the support 11 wherein the transponder 8 is arranged) to a series of cyclical deformations.

The test system 9 comprises a reader 13 that is configured to detect in radio-frequency the functioning of the transponder 8 during the cyclical deformations of the support 11. In use, the cyclical deformations of the support 11 are interrupted (that is to say that the test is terminated) when the reader 13 is no longer able to read the transponder 8 following a breakdown of the transponder 8. Typically, the reader 13 comprises an antenna 14 that is arranged inside the closed chamber 9 alongside the deforming unit 12 (in order to be in close proximity with the support 11 housed in the deforming unit 12) and a control device 15 arranged outside the closed chamber 9.

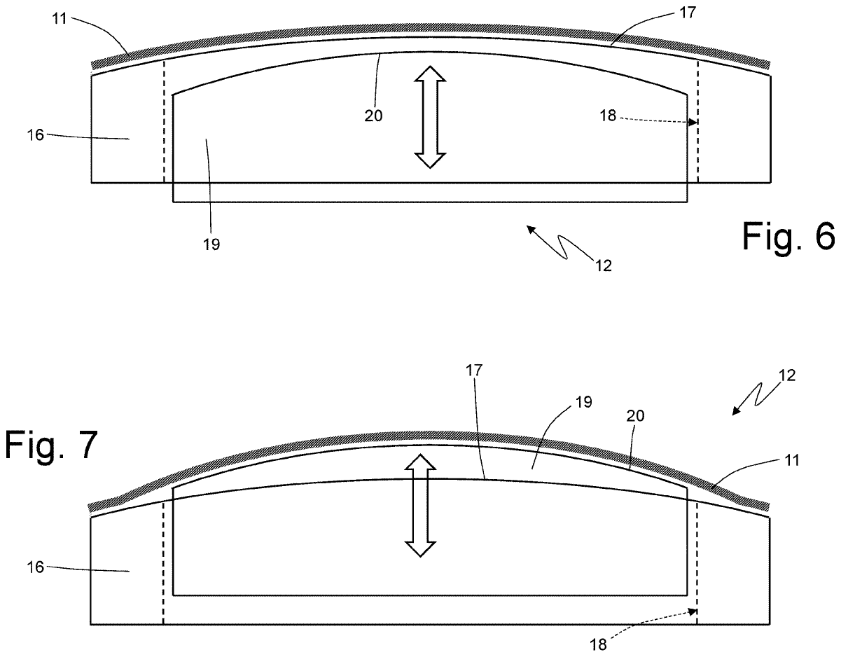

The deforming unit 12 is configured to cyclically deform the central area of the support 11, in such a way as to alternatively assume, at the central area of the support 11, the three-dimensional form F1 that the component (the lateral wall 7) assumes in the tire 1 when far from the footprint on the ground and the three-dimensional form F2 that the component (the lateral wall 7) assumes in the tire 1 at the footprint on the ground. In particular, the two boundary conditions assumed by the support 11 are shown in FIGS. 6 and 7; the support 11 (in schematic form) that assumes the three-dimensional form F1 is shown in FIG. 6, whilst the support 11 that assumes the three-dimensional form F2 is shown in FIG. 7.

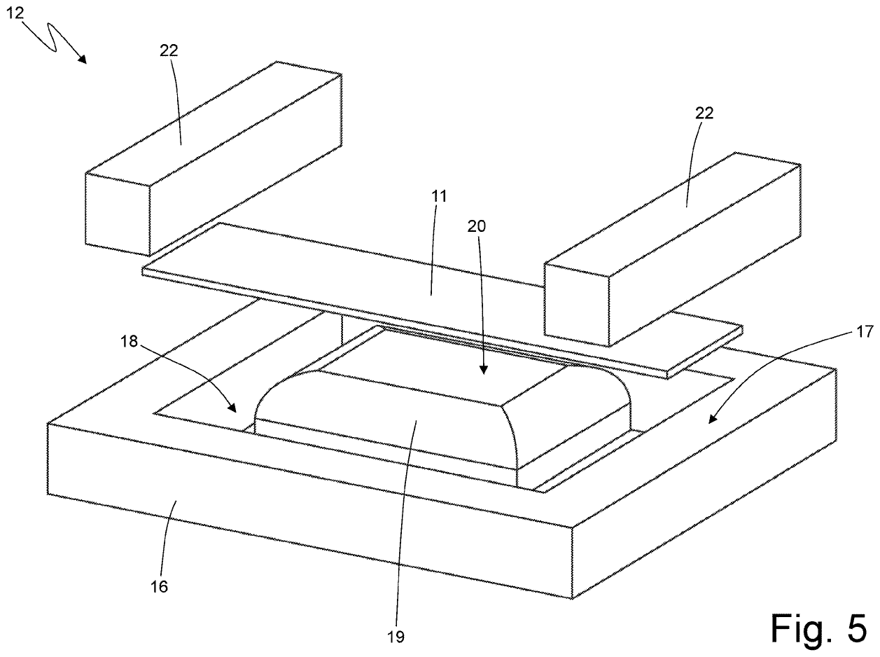

According to what is shown in FIGS. 4 and 5, the deforming unit 12 comprises a fixed base 16 (that is to say that when in use it does not perform any kind of movement) featuring a working surface 17 that reproduces the three-dimensional form F1. In particular, the fixed base 16 has the form of a rectangular frame having, centrally, a through opening 18 (of a rectangular form). According to other embodiments, not shown, the support 11 has a non-rectangular form and therefore, consequently, the fixed base 16 also has a non-rectangular form. The deforming unit 12 comprises a deforming body 19 having a working surface 20 that reproduces the three-dimensional form F2 and that faces the support 11; the deforming body 19 is arranged inside the through opening 18 of the fixed base 16, that is to say that it moves into the through opening 18 of the fixed base 16.

The deforming unit 12 comprises an actuator 21 that imparts an alternating movement (in the vertical direction) to the deforming body 19 that cyclically causes the deforming body 19 to press against the central area of the support 11 (that is to say the area wherein the transponder 8 is arranged) in order to deform the central area of the support 11. Therefore, in use, what is shown in FIGS. 6 and 7 is cyclically repeated: when the deforming body 19 is at the lowest point (retracted), the working surface 20 of the deforming body 19 does not touch the support 11 that is resting on the working surface 17 of the fixed base 16 and therefore assumes the form F1 (as shown in FIG. 6), whilst when the deforming body 19 is at the highest point (raised), the working surface 20 of the deforming body 19 does not touch (pushes) the support 11 that is resting on the working surface 20 of the deforming body 19 and therefore assumes the form F2 (as shown in FIG. 7). In other words, the alternating movement of the deforming body 19 cyclically deforms the central area of the support 11 in order cause the central area of the support 11 to alternatively assume the three-dimensional form F1 and the three-dimensional form F2.

According to a possible embodiment, the actuator 21 may be a permanent magnet electromagnetic shaker that has a similar structure to that of a loudspeaker and that comprises a coil that is mounted movable (in order to slide alternatively along a linear path) and that is immersed within an electromagnetic field that is generated by permanent magnets; when the coil is moved by an alternating electrical current it moves backwards and forwards at the same frequency as the alternating electrical current.

Initially, before activating the alternating movement of the deforming body 19, the support 11 is rested on the working surface 17 of the fixed base 16 that reproduces the three-dimensional form F1; subsequently the two ends of the support 11 are constrained to the fixed base 16 (that is to say the working surface 17 of the fixed base 16) by means of two respective retaining elements 22, wherein each thereof clamps the end of the support 11 against the fixed base 16 (that is to say against the working surface 17 of the fixed base 16). According to a preferred embodiment, each retaining element 22 is screwed to the fixed base 16 by means of a pair of screws. Once the support 11 has been rested upon and constrained to the working surface 17 of the fixed base 16, it is possible to activate the alternating movement of the deforming body 19 that cyclically causes the deforming body 19 to press against the central area of the support 11 in order to deform the central area of the support 11.

According to a preferred embodiment shown in FIG. 4, the test system 9 comprises a heating device 23 (climate controller) that is configured in order to heat (or if necessary also to cool) the closed chamber 10 to a predetermined test temperature (generally in the order of 50-70° C.) in order to reproduce the internal temperature of the tire 1 during use. According to a preferred embodiment, the heating (cooling) takes place by introducing warm (cold) air into the closed chamber 10.

In other words, the test system 9 subjects an area of the support 11, wherein the electronic device 8 is arranged, to a series of cyclical deformations in order to cause said area of the support 11 to alternatively assume the three-dimensional form F1 and the three-dimensional form F2. The two three-dimensional forms F1 and F2 are not “causal”, but are exactly the two boundary forms that the component (the lateral wall 7) of the tire 7 assumes in use.

The tire 1 may be of any type, that is to say intended for automobiles, motorcycles, buses, trucks, vans, bicycles, work vehicles, agricultural vehicles, airplanes.

In the preferred embodiment described above, an electronic component 8 (for example a transponder, but not only a transponder) that is intended to be coupled to a tire 1 component is subjected to a resilience test; the present invention may however find application in testing any type of electronic component that is subjected in use to periodic deformations, also within areas of application that are (completely) different from that of a tire.

The embodiments described herein may be combined without departing from the scope of protection of the present invention.

The test method described above has many advantages.

Firstly, the test method described above is very effective (that is to say that it exhibits high precision and high reliability) insofar as the results provided by the test method described above correspond very faithfully to results that may be encountered with actual tires. This significant result is obtained by virtue of the fact that the support 11 is exactly subjected (very accurately) to the same deformations whereto the component (the lateral wall 7) of the tire 1, that integrates the transponder 8, is subjected in use by virtue of the fact that it deforms the support 11 by using working surfaces 17 and 20 that are conformed according to the three-dimensional form F1 and F2 (determined based upon the actual deformations of the tire 1).

Furthermore, the test method described above is also very efficient insofar as it makes it possible to perform tests in a very fast and cost effective manner. In particular, the implementation of the support 11 is simple and rapid (it is basically a matter of making a rectangular rubber strip with dimensions of the order of 75×25 mm, wherein the transponder 8 is internally arranged). Furthermore, a test may be performed much quicker than an “on the road” test using an actual tire 1: the actuator 21 may operate at 50-70 Hz which corresponds to a road speed of 400-500 km/h (therefore many times faster than an “on the road” test using an actual tire 1).

Finally, the test system 9 described above is simple and economical to implement insofar as it calls for the use of components that are easily found on the market at no great cost; in particular, the fixed base 16 and the deforming body 19 (having the respective working surfaces 17 and 20 that must have the three-dimensional forms F1 and F2) may be manufactured from a plastic material by means of additive manufacturing (3D printing) with low lead times and reduced manufacturing costs (to this end it is important to note that the fixed base 16 and the deforming body 19 are not subjected to elevated mechanical stresses and they may, therefore, also be manufactured using conventional plastic materials.

### LIST OF REFERENCE NUMBERS IN THE FIGURES

1 tire
2 carcass
3 beads
4 tread
5 tread belt
6 innerliner
7 sidewalls
8 transponder
9 test system
10 closed chamber
11 support
12 deforming unit
13 reader
14 antenna
15 control device
16 fixed base
17 working surface
18 pass-through opening
19 deforming body
20 working surface
21 actuator
22 retaining element
23 heating device
F1 three-dimensional form
F2 three-dimensional form

1-13. (canceled)

14. A method for testing the resilience of an electronic device that is configured to be coupled to at least one component of an elastic body and subjected to periodic deformations when in use therewith, the method comprising:
providing a support containing the electronic device;
determining a first form that the at least one component of the tire assumes in use;
determining a second form that the at least one component of the tire assumes in use and that is different than the first form;
cyclically deforming the area of the support in order to cause the area of the support to assume the first form and the second form; and
detecting an operation of the electronic device during the cyclical deformations of the support.

15. The method of claim 14, wherein the support is rested upon a first working surface of a base that reproduces the first form.

16. The method of claim 15, wherein the base has a through opening wherethrough a deforming body is arranged having a second working surface that reproduces the second form and that is facing the support.

17. The method of claim 16, further comprising imparting an alternating movement to the deforming body causing the deforming body to cyclically press against the support in order to deform the support.

18. The method of claim 15, further comprising constraining two opposite ends of the support to the base.

19. The method of claim 18, wherein the ends of the support are constrained to the base via a corresponding retaining element that clamps the ends of the support to the base.

20. The method of claim 19, wherein each retaining element is screwed to the base.

21. The method of claim 15, wherein the base has the form of a frame.

22. The method of claim 14, wherein the first form has an average radius of curvature that is greater than the average radius of curvature of the second form.

23. The method of claim 14, further comprising:
arranging the support within a closed chamber; and
adjusting the closed chamber to a predetermined test temperature.

24. The method of claim 23, wherein the closed chamber is adjusted to the predetermined test temperature by introducing warm or cold air into the closed chamber.

25. The method of claim 14, wherein the elastic body is a tire.

26. The method of claim 25, wherein:
the at least one component of the tire assumes the first form when it is substantially opposite from a footprint on the ground and undeformed; and
the at least one component of the tire assumes the second form when it is at the footprint on the ground and deformed.

27. A system for testing the resilience of an electronic device that is configured to be coupled to at least one component of an elastic body and subjected to periodic deformations when in use therewith, the system comprising:
a deforming unit configured to cyclically deform an area of a support wherein the electronic device is arranged in a way to cause the area of the support to alternatively assume a first form which the at least one component assumes in use and a second form which the at least one component assumes in use and that is different from the first form; and
a reader configured to detect an operation of the electronic device during the cyclical deformations of the support.

28. The system of claim 27, wherein:
the support is rested upon a first working surface of a base that reproduces the first form; and
the base has a through opening wherethrough a deforming body is arranged having a second working surface that reproduces the second form and that is facing the support.

29. The system of claim 28, wherein the deforming unit is configured to impart an alternating movement to the deforming body causing the deforming body to cyclically press against the support in order to deform the support.

30. The system of claim 28, wherein two opposite ends of the support are constrained to the base via a corresponding retaining element that clamps the ends of the support to the base.

31. The system of claim 27, wherein the base has the form of a frame.

32. The system of claim 27, wherein the first form has an average radius of curvature that is greater than the average radius of curvature of the second form.

33. The system of claim 27, further comprising a closed chamber wherein the support is arranged, and wherein the closed chamber is adjusted to a predetermined test temperature.

34. (canceled)
